(19) United States
(12) Patent Application Publication
(10) Pub. No.: US 2012/0126421 A1
(43) Pub. Date: May 24, 2012

(54) Semiconductor Devices and Methods of Forming the Same

(76) Inventors: Young-Ho Lee, Hwaseong Si (KR); Keonsoo Kim, Suwon-si (KR); Hyunchul Back, Suwon-si (KR); Jinhyun Shin, Suwon-si (KR); Seungwook Choi, Suwon-si (KR)

(21) Appl. No.: 13/270,990

(22) Filed: Oct. 11, 2011

(30) Foreign Application Priority Data
Nov. 18, 2010 (KR) 10-2010-0115105

(51) Int. Cl. H01L 23/48

(52) U.S. Cl. 257/774; 257/E23.011

(57) ABSTRACT

A method of forming a semiconductor device may include forming a contact mold layer on a substrate; forming an interconnection mold layer on the contact mold layer that includes a material having an etching selectivity with respect to the contact mold layer; forming grooves in the interconnection mold layer that extend in a first direction and expose the contact mold layer; forming holes in the contact mold layer connected to the grooves by etching a part of the contact mold layer exposed by the groove; and forming contact portions in the holes and interconnections in the groove. A diffusion coefficient of mobile atoms in the contact mold layer is greater than a diffusion coefficient of mobile atoms in a nitride.

### CROSS-REFERENCE TO RELATED APPLICATIONS

This U.S. non-provisional patent application claims priority under 35 U.S.C. §119 from Korean Patent Application No. 10-2010-0115105, filed on Nov. 18, 2010 in the Korean Intellectual Property Office (KIPO), the contents of which are herein incorporated by reference in their entirety.

### BACKGROUND

Embodiments of the present inventive concept are directed to semiconductor devices and methods of forming the same, and more particularly, to a semiconductor device including interconnection structures and a method of forming the same.

Semiconductor devices have been an important element in the electronics industry because of properties such as miniaturization, multi-function and/or low manufacturing cost. Semiconductor devices may be classified into semiconductor memory devices for storing data, semiconductor processing units for performing operations on data, and hybrid semiconductor devices that include memory elements and processing elements.

As electronic devices achieve higher speeds and lower power consumption, semiconductor devices incorporated in the electronic devices are also required to have higher operating speeds and/or lower operating voltages. To meet those requirements, semiconductor devices are becoming more highly integrated. As semiconductor devices become more highly integrated, the reliability of semiconductor devices may deteriorate. However, semiconductor devices also need to become more reliable.

### SUMMARY

Embodiments of the present inventive concept may provide semiconductor devices with improved reliability and methods of forming the same.

Embodiments of the present inventive concept may provide semiconductor devices optimized for high integration and methods of forming the same.

Embodiments of the inventive concept provide a method of forming a semiconductor device. The method may include forming a contact mold layer on a substrate; forming an interconnection mold layer on the contact mold layer, wherein the interconnection mold layer comprises a material having an etching selectivity with respect to the contact mold layer; forming grooves in the interconnection mold layer that extend in a first direction and expose the contact mold layer; forming holes in the contact mold layer connected to the grooves by etching a part of the contact mold layer exposed by the grooves; and forming contact portions in the holes and interconnections in the grooves.

Embodiments of the inventive concept also provide a semiconductor device. The semiconductor device may include a contact mold layer disposed on a substrate; interconnections disposed on the contact mold layer and extending in parallel a first direction and having a width in a second direction perpendicular to the first direction; a capping film disposed on a top surface of the interconnections; and a contact portion extending downward from a bottom surface of the interconnection to penetrate the contact mold layer. A width in the second direction of the interconnections is the substantially same with a width in the second direction of the contact portions.

Embodiments of the inventive concept also provide a semiconductor device. The semiconductor device may include a contact mold layer disposed on a substrate, interconnections disposed on the contact mold layer and extending in parallel in a first direction and having a width in a second direction perpendicular to the first direction; contact portions extending downward from a bottom surface of the interconnection to penetrate the contact mold layer; and a dielectric film filling at least a part of a space between the adjacent interconnections on the contact mold layer. The dielectric film may comprise a material having a dielectric constant less than that of a nitride. A diffusion coefficient of mobile atoms in the contact mold layer may be greater than a diffusion coefficient of mobile atoms in a nitride.

### BRIEF DESCRIPTION OF THE FIGURES

FIGS. 1A through 11A are top plan views for illustrating a method of forming a semiconductor device in accordance with embodiments of the inventive concept.

FIGS. 1B through 11B are cross sectional views taken along the lines I-I′ and II-II′ of FIGS. 1A through 11A to illustrate a method of forming a semiconductor device in accordance with embodiments of the inventive concept.

FIG. 12A is a top plan view for illustrating a semiconductor device in accordance with embodiments of the inventive concept.

FIG. 12B is a cross sectional view taken along the lines I-I′ and II-II′ of FIG. 12A to illustrate a semiconductor device in accordance with embodiments of the inventive concept.

FIG. 13 is a cross sectional view taken along the lines I-I′ and II-II′ of FIG. 12A to illustrate a modified semiconductor device in accordance with other embodiments of the inventive concept.

FIG. 14A is a top plan view that illustrates a method of forming a semiconductor device in accordance with other embodiments of the inventive concept.

FIG. 14B is a cross sectional view taken along the lines I-I′ and II-II′ of FIG. 14A to illustrate a method of forming a semiconductor device in accordance with other embodiments of the inventive concept.

FIG. 15A is a top plan view for illustrating a semiconductor device in accordance with other embodiments of the inventive concept.

FIG. 15B is a cross sectional view taken along the lines I-I′ and II-II′ of FIG. 15A to illustrate a semiconductor device in accordance with other embodiments of the inventive concept.

FIG. 16 is a cross sectional view taken along the lines I-I′ and II-II′ of FIG. 14A to illustrate a modified semiconductor device in accordance with other embodiments of the inventive concept.

FIG. 17 is a cross sectional view taken along the lines I-I′ and II-II′ of FIG. 15A to illustrate a modified semiconductor device in accordance with other embodiments of the inventive concept.

FIG. 18 is a block diagram illustrating an example of a memory system including a semiconductor device in accordance with embodiments of the inventive concept.

FIG. 19 is a block diagram illustrating an example of a memory card including a semiconductor device in accordance with embodiments of the inventive concept.

### DETAILED DESCRIPTION OF EXEMPLARY EMBODIMENTS

Exemplary embodiments of the inventive concept will be described below in more detail with reference to the accompanying drawings. Exemplary embodiments of the inventive concept may, however, be embodied in different forms and should not be constructed as limited to the embodiments set forth herein. Like numbers refer to like elements throughout. It will also be understood that when an element such as a layer, region or substrate is referred to as being “on” or “onto” another element, it may lie directly on the other element or intervening elements or layers may also be present.

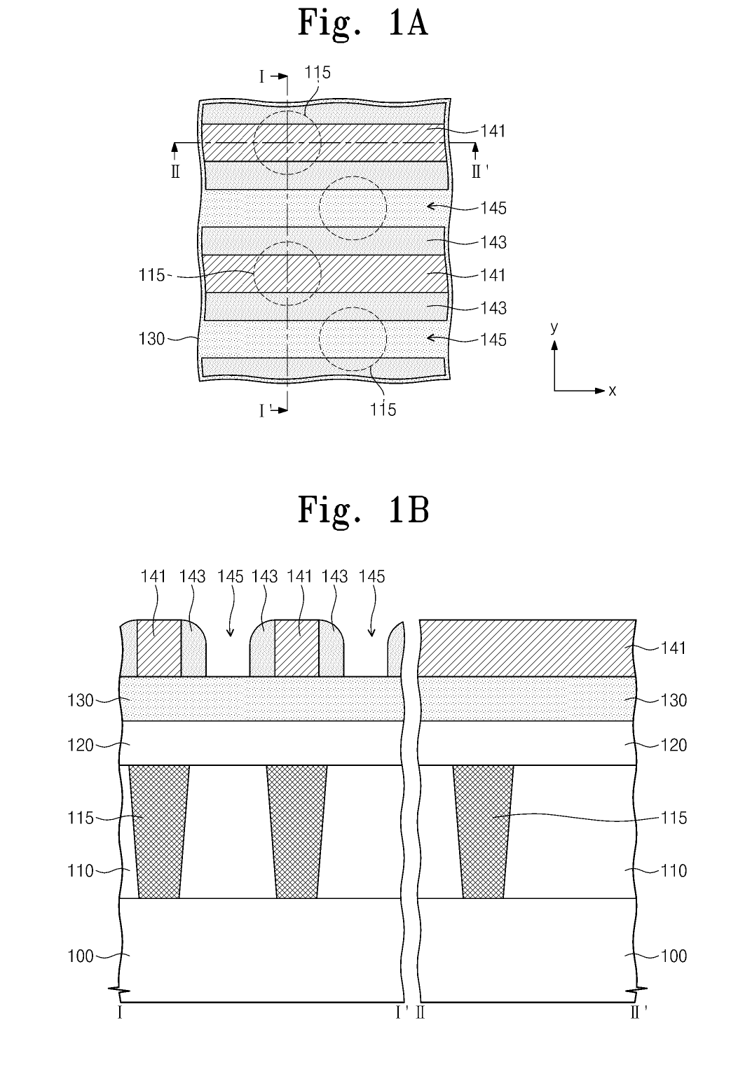

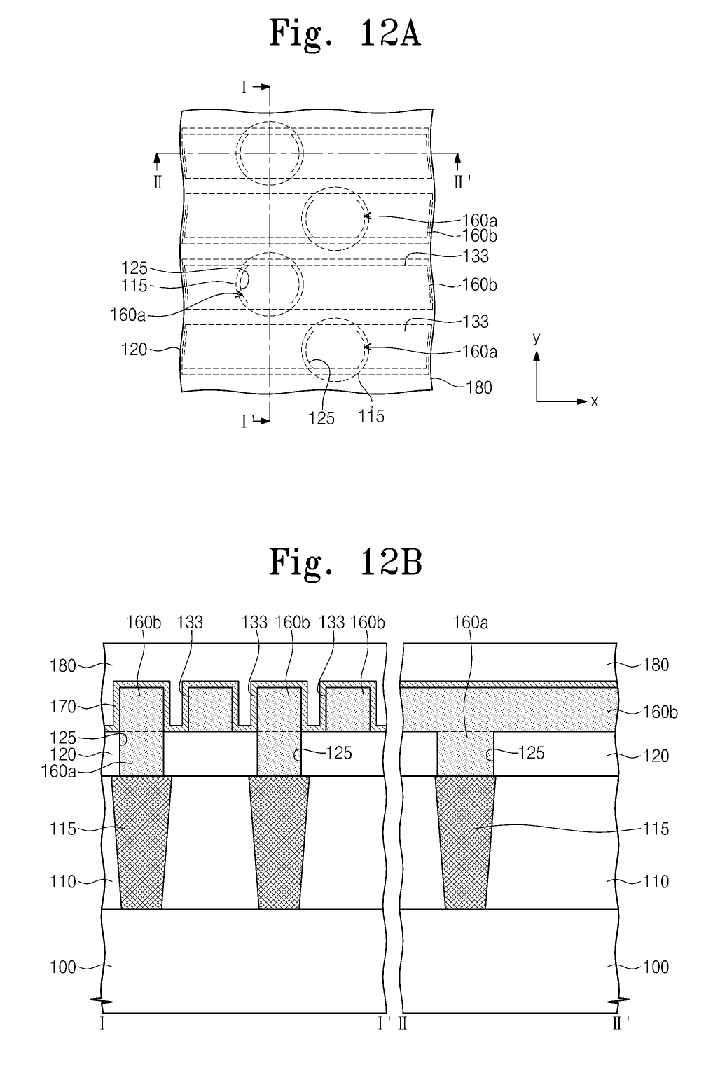

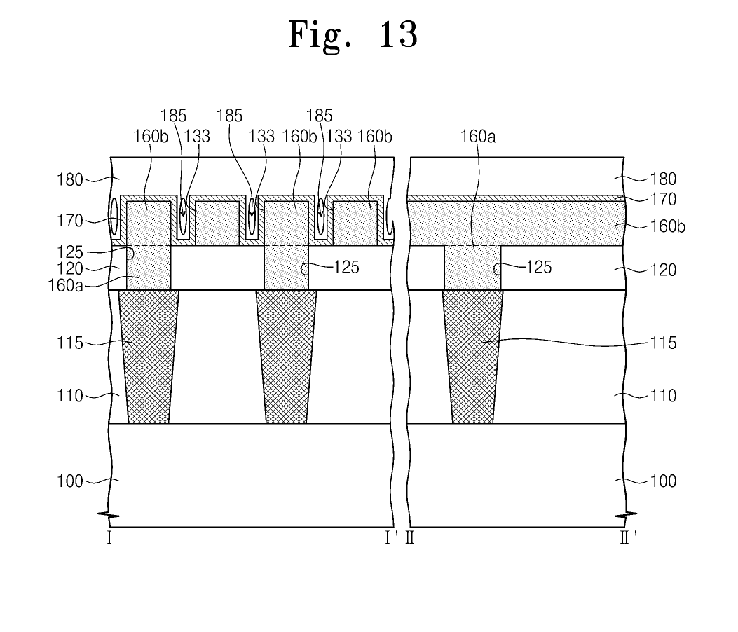

Hereinafter, a method of forming a semiconductor device in accordance with an embodiment of the inventive concept is described with reference to FIGS. 1A to 12A, 1B to 12B, and 13. FIGS. 1A through 11A are top plan views for illustrating a method of forming a semiconductor device in accordance with embodiments of the inventive concept. FIGS. 1B through 11B are cross sectional views taken along the lines I-I′ and II-II′ of FIGS. 1A through 11A to illustrate a method of forming a semiconductor device in accordance with embodiments of the inventive concept. FIG. 12A is a top plan view for illustrating a semiconductor device manufactured by methods in accordance with embodiments of the inventive concept. FIG. 12B is a cross sectional view taken along the lines I-I′ and II-II′ of FIG. 12A to illustrate a semiconductor device manufactured by methods in accordance with embodiments of the inventive concept. FIG. 13 is a cross sectional view taken along the lines I-I′ and II-II′ of FIG. 12A to illustrate a modified semiconductor device in accordance with other embodiments of the inventive concept.

Referring to FIGS. 1A and 1B, an interlayer dielectric film 110 may be formed on a substrate 100 and conductive pillars 115 penetrating the interlayer dielectric film 110 may be formed on the substrate 100. The substrate 100 may be a silicon substrate, a germanium substrate or a silicon-germanium substrate. The interlayer dielectric film 110 may be formed as a single layer or as multiple layers. The interlayer dielectric film 110 may include an oxide, a nitride and/or an oxynitride.

The conductive pillars 115 may be arranged along a first column and a second column when viewed in a top plan view. The first column and the second column may be spaced apart from each other in a first direction. The first column and the second column may be parallel to a second direction perpendicular to the first direction. The first column of conductive pillars may not overlap the second column of conductive pillars in the first direction. Thus, the conductive pillars 115 may have a zigzag pattern in the second direction. Top surfaces of the conductive pillars 115 may be coplanar with top surfaces of the interlayer dielectric film 110. The first direction may correspond to an x axis direction in FIG. 1 A and the second direction may correspond to a y axis direction in FIG. 1A.

The conductive pillar 115 may include a conductive material. For example, the conductive pillar 115 may include at least one of a doped semiconductor (e.g., doped silicon), a metal (e.g., tungsten), a conductive metal nitride (e.g., titanium nitride or tantalum nitride), a transition metal (e.g., titanium, tantalum, etc.) or a conductive metal-semiconductor compound (e.g., metal silicide).

Subsequently, a contact mold layer 120 and an interconnection mold layer 130 may be sequentially formed on the substrate 100. The contact mold layer 120 and the interconnection mold layer 130 may be formed by a chemical vapor deposition (CVD) process or a physical vapor deposition (PVD) process. The contact mold layer 120 may be formed as a single layer or as multiple layers.

A diffusion coefficient of mobile atoms in the contact mold layer 120 may be greater than a diffusion coefficient of mobile atoms in a nitride. The mobile atoms may include atoms that can freely move in a film. For example, the mobile atom may be hydrogen.

The interconnection mold layer 130 may be formed as a single layer or as multiple layers. The interconnection mold layer 130 may include a material having an etching selectivity with respect to the contact mold layer 120. For example, the interconnection mold layer 130 may include a nitride and the contact mold layer 120 may include an oxide.

According to an embodiment of the inventive concept, since the diffusion coefficient of the mobile atoms in the contact mold layer 120 is greater than the diffusion coefficient of mobile atoms in a nitride, mobile atoms in films of the semiconductor device may be emitted from the device through the contact mold layer 120, minimizing effects that occur due to the presence of these mobile atoms.

Mask line patterns 141 extending in the first direction may be formed on the interconnection mold layer 130. The mask line patterns 141 may be spaced apart from one another in the second direction. A space between the mask line patterns 141 may be greater than a width of the mask line pattern 141.

A hard mask film may be conformally formed over the substrate 100 including the mask line patterns 141. The hard mask film may be anisotropically etched to expose a top surface of the interconnection mold layer 130 to form hard mask patterns 143 on both sidewalls of the mask line pattern 141 and to form a first opening 145 exposing the interconnection mold layer 130 between the adjacent mask line patterns 141. The hard mask patterns 143 may have a spacer shape on both sidewalls of the mask line pattern 141 and may extend in the first direction along side of the mask line patterns 141. The hard mask patterns 143 may be spaced apart from one another in the second direction. Each hard mask pattern 143 may have a first sidewall and a second sidewall parallel to each other. The second sidewall of the hard mask pattern 143 may be in contact with a sidewall of the mask line pattern 141. The first opening 145 may be defined by the first sidewalls of the hard mask patterns 143 of adjacent mask line patterns 141. The first sidewall of the hard mask pattern 143 may correspond to a portion of the hard mask film exposed to the anisotropic etching and the second sidewall of the hard mask pattern 143 may correspond to a portion of the hard mask film not exposed to the anisotropic etching. The first opening 145 may extend in the first direction.

The hard mask pattern 143 may include a material having an etching selectivity with respect to the interconnection mold layer 130. The mask line pattern 141 may be formed of a material having an etching selectivity with respect to the hard mask pattern 143. In addition, the mask line pattern 141 may be formed of a material having an etching selectivity with respect to the interconnection mold layer 130. For example, in the case that the interconnection mold layer 130 includes a nitride, the mask line pattern 141 may include an oxide and/or an oxynitride and the hard mask pattern 143 may include a semiconductor material (e.g., polysilicon).

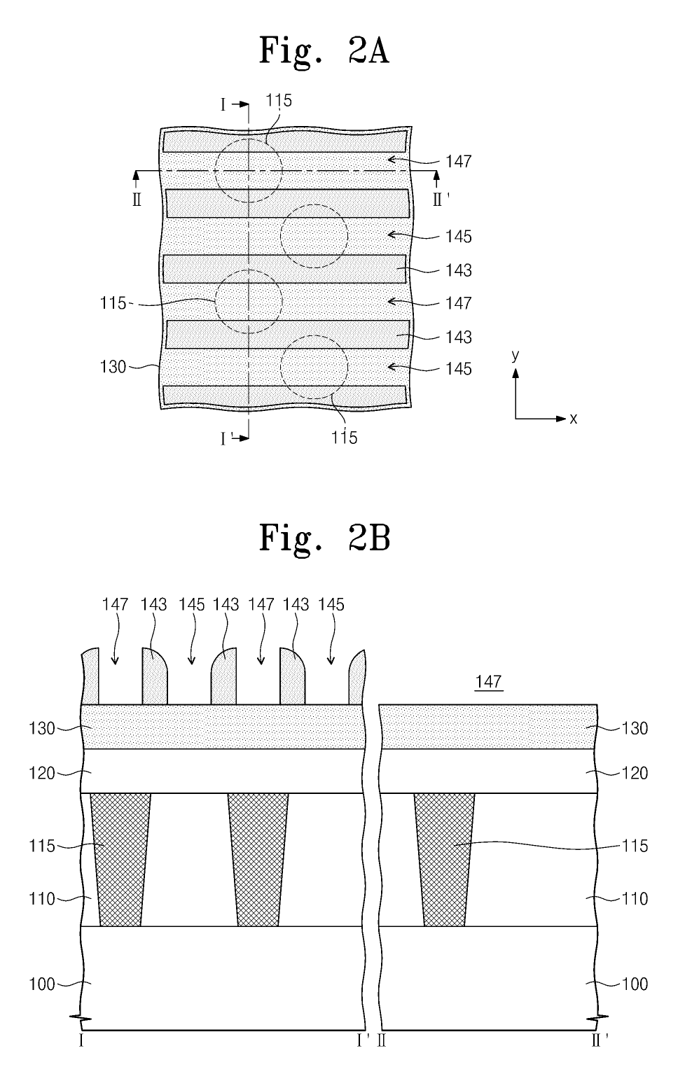

Referring to FIGS. 2A and 2B, the mask line pattern 141 may be removed to form a second opening 147 exposing the interconnection mold layer 130. The second opening 147 may be an area where the mask line pattern 141 is removed, defined by the second sidewalls of adjacent hard mask patterns 143. The first openings 145 and the second openings 147 may be repeatedly and alternately disposed in the second direction.

A width of a bottom surface of the first opening 145 in the second direction may be substantially equal to a width of a bottom surface of the second opening 147 in the second direction. According to an embodiment, uniform widths of the bottom surfaces of the first and second openings 145 and 147 may be achieved by controlling a thickness of the hard mask film. For example, as described above, a space between the mask line patterns 141 may be greater than a width of the mask line pattern 141. A thickness of the hard mask film may be equal to half of a difference of the width of the space between the mask line patterns 141 and the width of the mask line pattern 141. Therefore, the widths of bottom surfaces of the first and second openings 145 and 147 may be equal to each other.

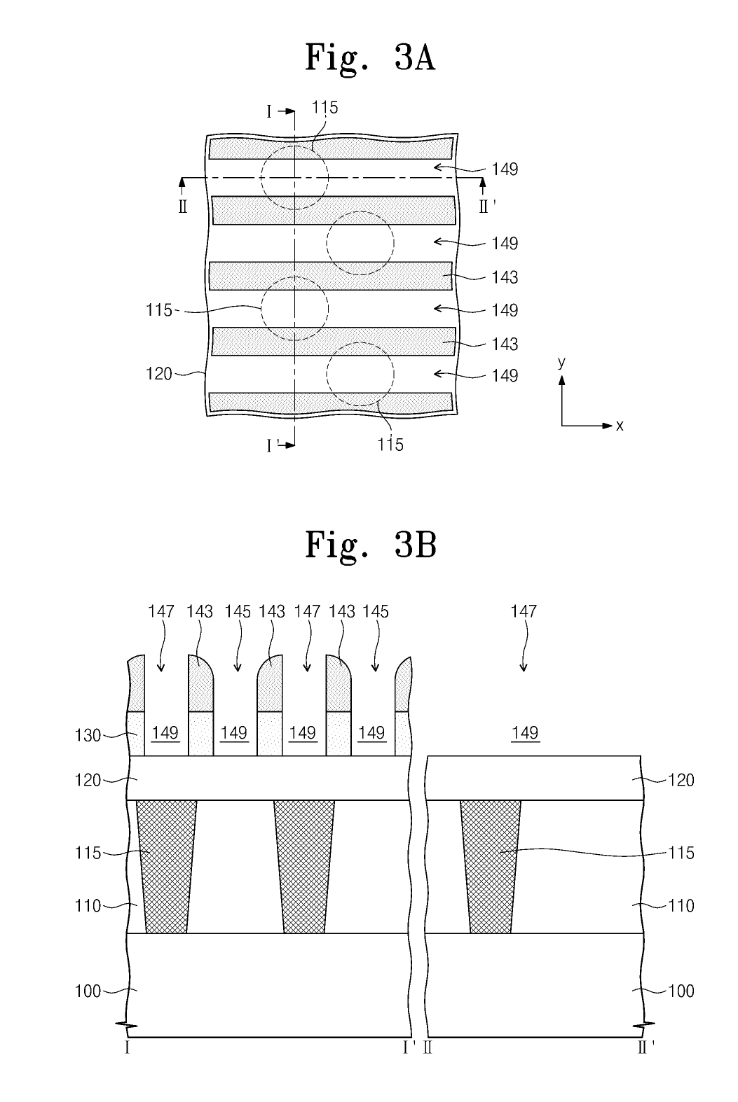

Referring to FIGS. 3A and 3B, the interconnection mold layer 130 may be etched using the hard mask patterns 143 as an etching mask to form grooves 149. Each of the grooves 149 may expose the contact mold layer 120. The grooves 149 may be formed under the first openings 145 and the second openings 147. Each of the grooves 149 may pass over each of the conductive pillars 115. The grooves 149 may extend in parallel in the first direction.

According to a method of forming the hard mask patterns 143, the first and second openings 145 and 147 may be formed using the mask line patterns 141 and the hard mask patterns 143. If the mask line patterns 141 have a minimum line width definable by a photolithography process, each of the first openings 145 and the second openings 147 may be formed to have a width that is less than the minimum line width definable by a photolithography process. Thus, a highly integrated semiconductor device may be fabricated. Consequently, the width of each of the grooves 149 formed using the first and second openings 145 and 147 may be minimized.

However, embodiments of the inventive concept are not limited thereto. For example, the hard mask patterns 143 may be formed by forming a hard mask film on the interconnection mold layer 130 and then patterning the hard mask film. In this case, openings defined by the hard mask patterns 143 may be formed at the same time.

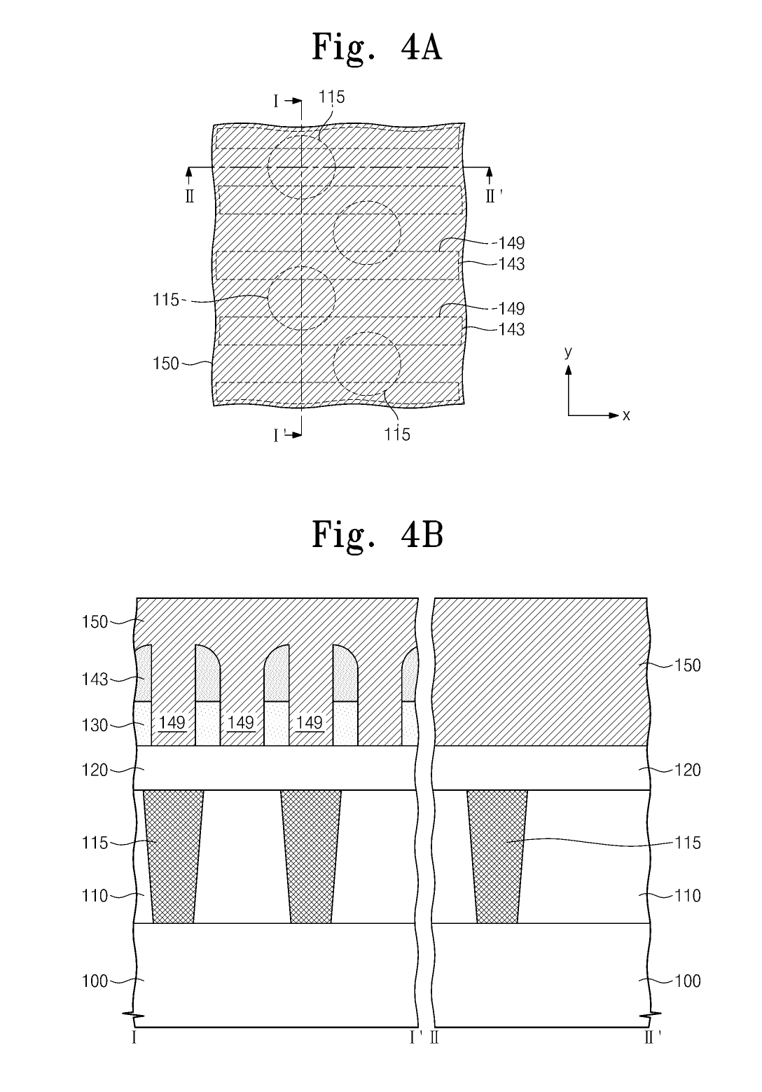

Referring to FIGS. 4A and 4B, a mask film 150 may be formed over the substrate including the hard mask patterns 143 and the grooves 149. The mask film 150 may fill the first and second openings 145 and 147 and the grooves 149. The mask film 150 may be a photoresist film or a spin on hard mask (SOH) film.

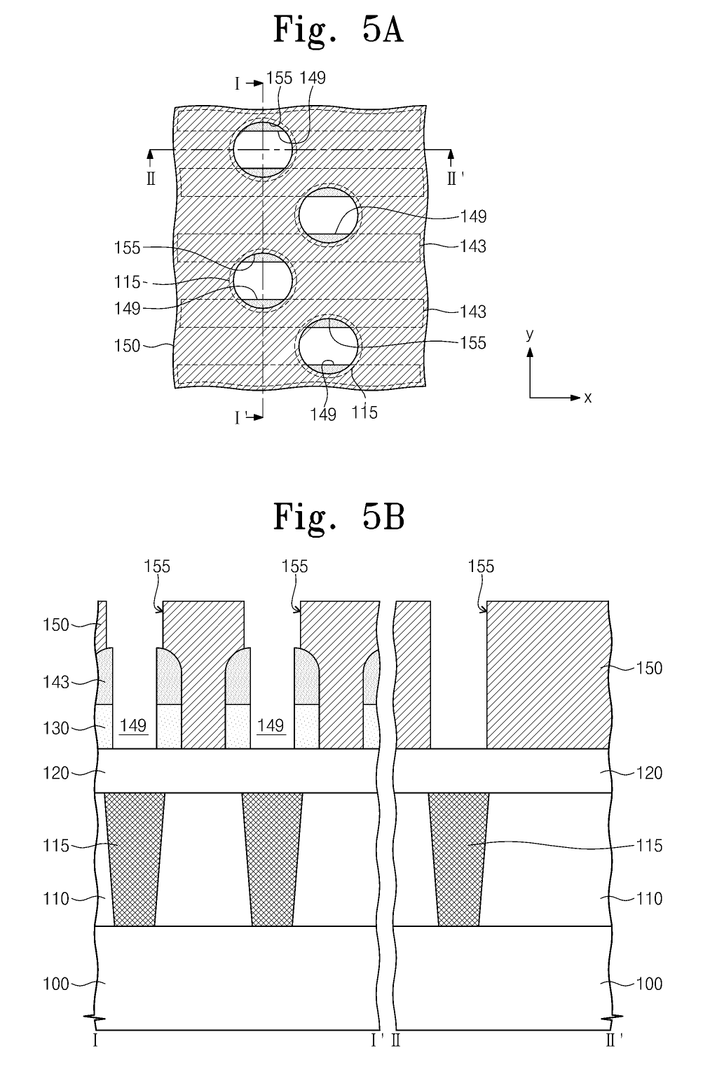

Referring to FIGS. 5A and 5B, the mask film 150 may be patterned to faun openings 155. If the mask film 150 is a photoresist film, the mask film 150 may be patterned by a photolithography process to form the openings 155. If the mask film 150 is a spin on hard mask (SOH) film, the openings 155 may be formed by a photolithography process and a dry etching process.

Each of the openings 155 may expose the part of the contact mold layer 120 exposed by the groove 149. The contact mold layer 120 in the groove 149 exposed by the openings 155 may be located on a top surface of the conductive pillar 115. In other words, each of the openings 155 may be located over a top surface of a conductive pillar 115. A width of the opening 155 may be greater than a width of each of the grooves 149. Thus, each of the openings 155 may expose a part of the hard mask pattern 143.

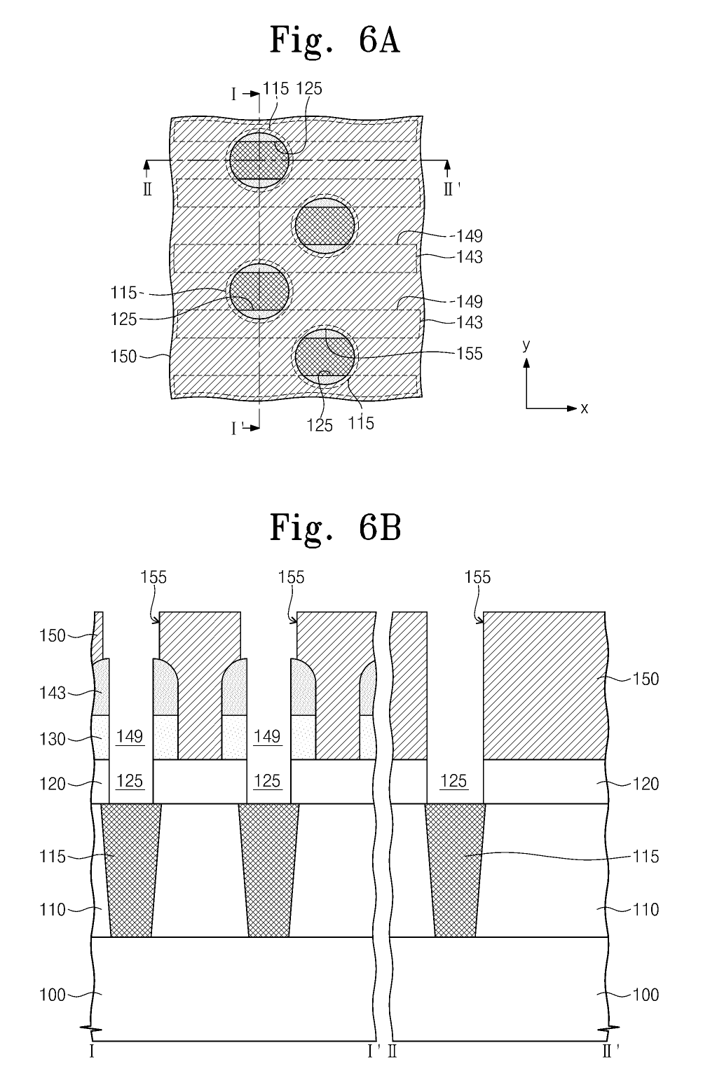

Referring to FIGS. 6A and 6B, the exposed contact mold film 120 may be etched using the mask film 150 and the exposed hard mask patterns 143 to form contact holes 125 exposing the conductive pillars 115.

As the exposed hard mask patterns 143 are used as an etching mask, the contact hole 125 may include a pair of first inner sidewalls aligned with both inner sidewalls of the groove 149. The first inner sidewalls of the contact hole 125 may be parallel to each other in the first direction and may be spaced apart from each other in the second direction. Also, the contact hole 125 may include second inner sidewalls aligned with a part of the opening 155 between the hard mask patterns 143 and spaced apart from each other in the first direction. The second inner sidewalls of the contact hole 125 may be curved.

Since the contact hole 125 is aligned with both sidewalls of the groove 149, a misalignment between the groove 149 and the contact hole 125 may not occur. In particular, the groove 149 and the contact hole 125 may not be misaligned in the second direction and/or in a direction anti-parallel to the second direction. Thus, a manufacturing process margin of semiconductor device may be improved.

According to embodiments of the inventive concept, since the interconnection mold layer 130 includes a material having an etching selectivity with respect to the contact mold layer 120, etching of the contact mold layer 120 may be minimized when etching the interconnection mold layer 130 to form the contact holes 125. That is, an etch-stop film between the interconnection mold layer 130 and the contact mold layer 120 may be omitted. Consequently, a process for forming a semiconductor device may be simplified and a cost for manufacturing a semiconductor device may be reduced.

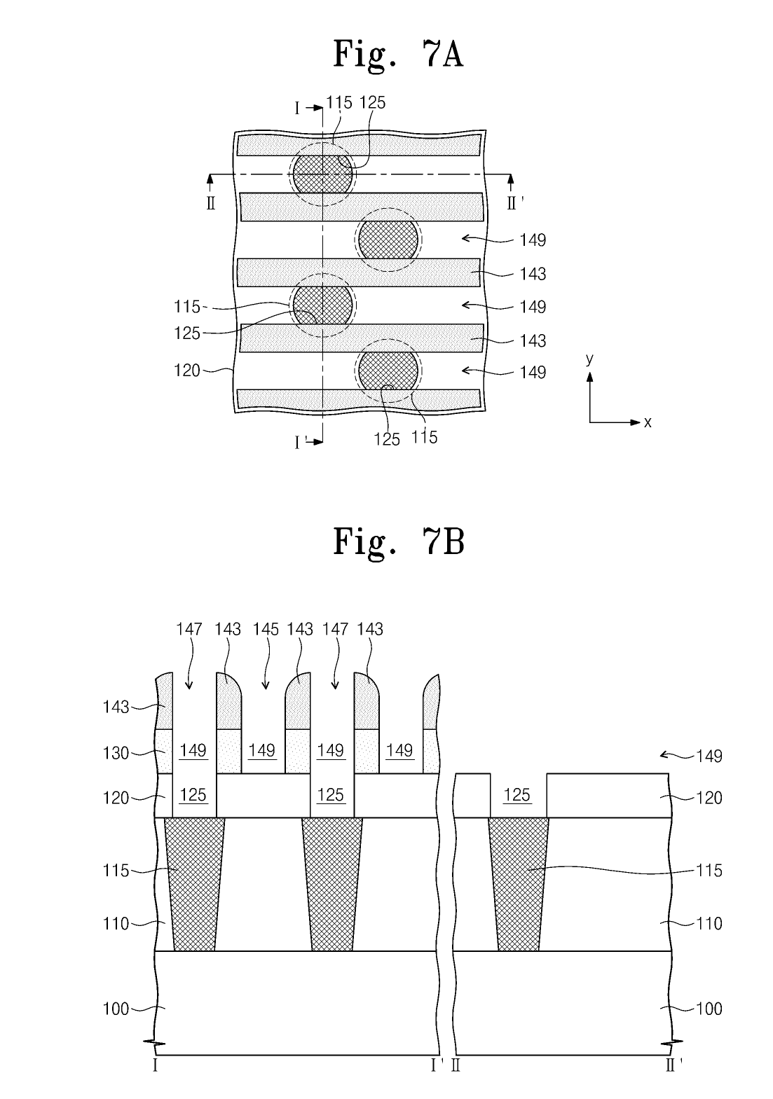

Referring to FIGS. 7A and 7B, the remaining mask film 150 may be removed, exposing other portions of the hard mask patterns 143 and the contact mold layer 120 in the groove 149. According to an embodiment, the mask film 150 may be removed by a wet etching process.

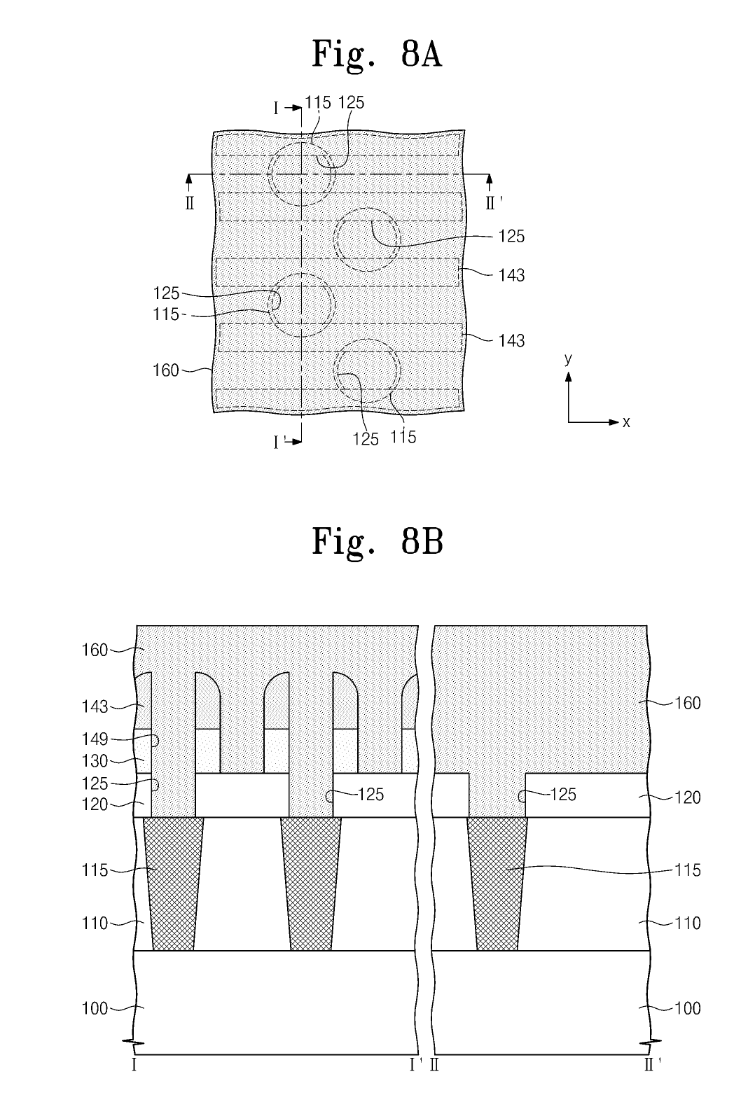

Referring to FIGS. 8A and 8B, a conductive film 160 filling the contact holes 125 and the grooves 149 may be formed over an entire surface of the substrate 100. The conductive film 160 may include a metal such as tungsten, aluminum, copper, etc. The conductive film 160 may also further include a barrier metal, such as titanium nitride or tantalum nitride, to minimize metal diffusion. In addition, the conductive film may further include a glue layer such as titanium or tantalum. According to an embodiment, as illustrated in FIG. 8B, the conductive film 160 may be formed on the remaining hard mask patterns 143.

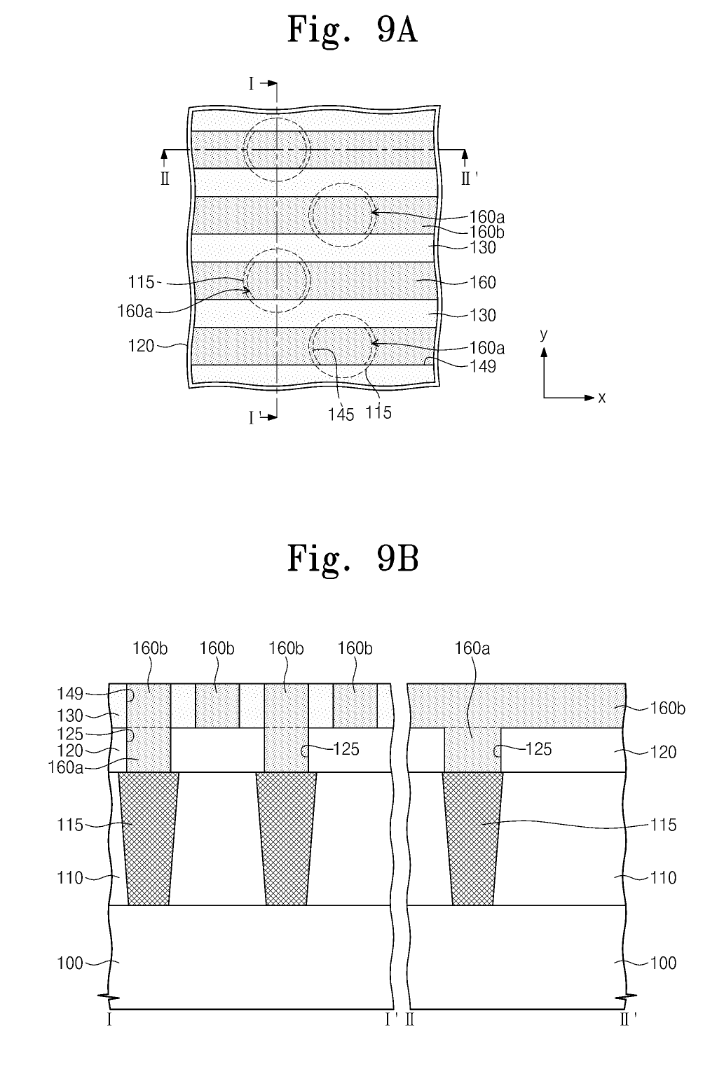

Referring to FIGS. 9A and 9B, the conductive film 160 may be planarized down to a top surface of the interconnection mold layer 130 to form a contact portion 160a filling the contact hole 125 and an interconnection 160b filling the groove 149. Planarizing the conductive film 160 may remove the hard mask patterns 143. The conductive film 160 may be planarized by a chemical mechanical polishing (CMP) process.

A top surface of the contact portion 160a may be substantially even with a top surface of the contact mold layer 120. Thus, the contact portion 160a may be surrounded by the contact mold layer 120.

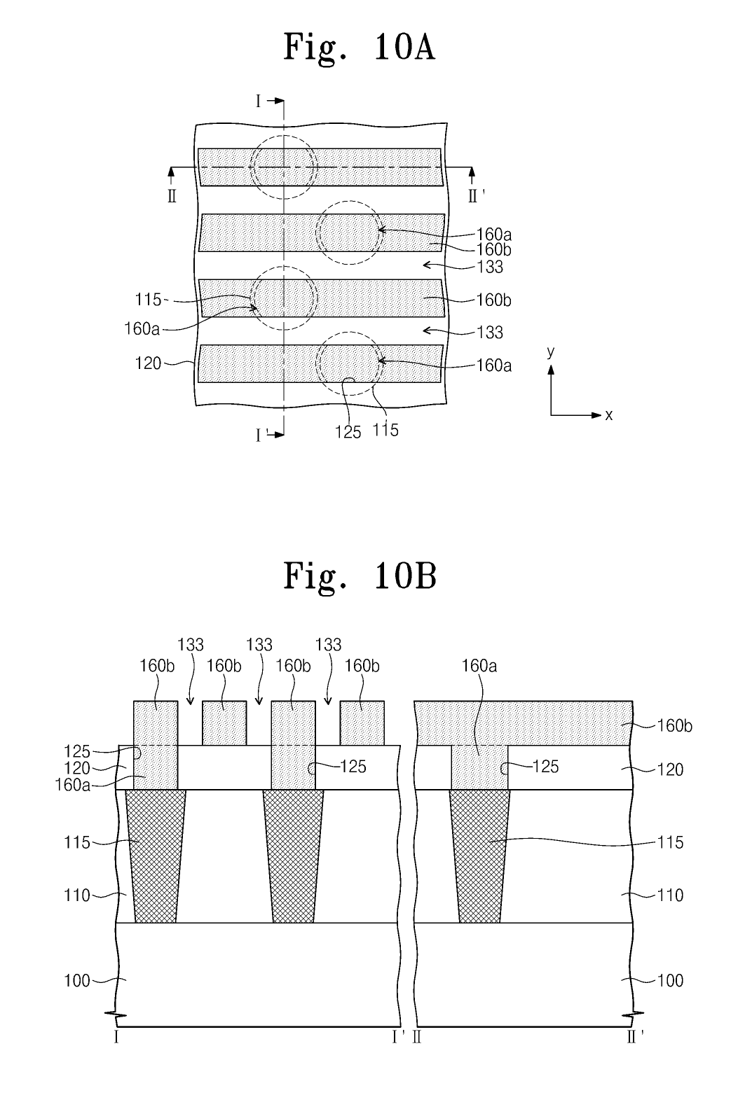

Referring to FIGS. 10A and 10B, the interconnection mold layer 130 between the interconnections 160b may be removed. Thus, spaces 133 may be formed between the interconnections 160b that may expose the contact mold layer 120. Spaces 133 may have sidewalls defined by the adjacent sidewalls of the interconnections 160b and bottom surfaces defined by the top surface of the contact mold layer 120. The interconnection mold layer 130 between the interconnections 160b may be removed by an anisotropic etching or an isotropic etching.

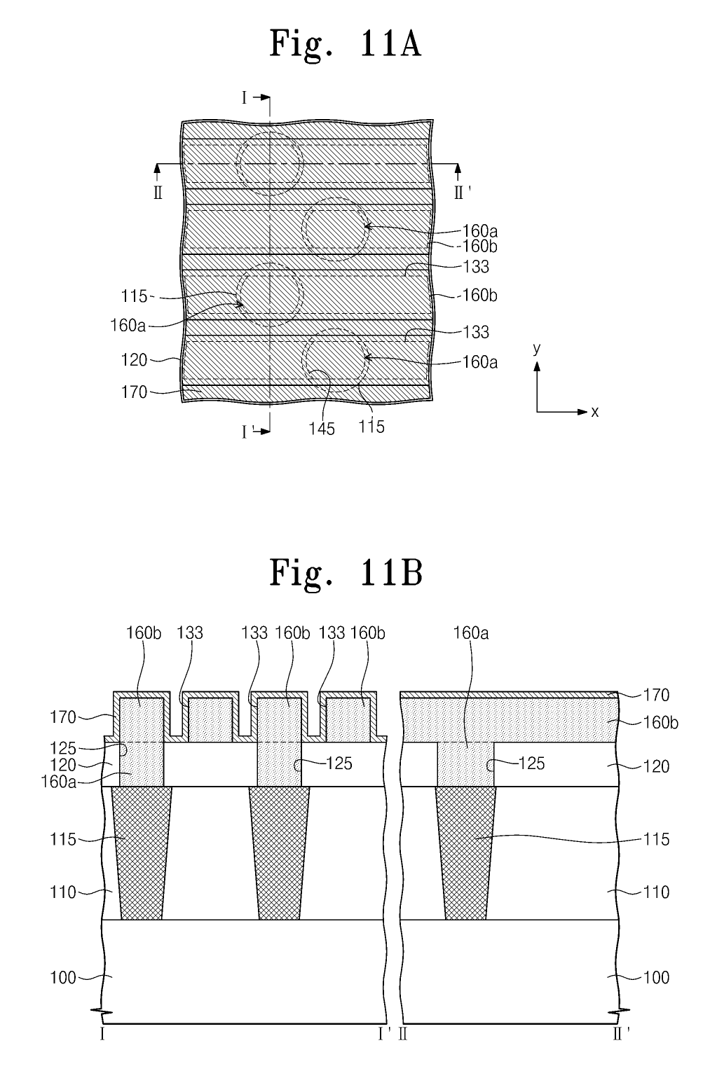

Referring to FIGS. 11A and 11B, a capping film 170 may be formed on the substrate 100. The capping film 170 may conformally cover the top surfaces of the interconnections 160b and the sidewalls of the spaces 133. The capping film 170 may include a dielectric film deposited by a plasma chemical vapor deposition process. For example, the capping film 170 may include a nitride.

According to an embodiment, forming the capping film 170 may include depositing a dielectric film using a plasma chemical vapor deposition process and reacting the dielectric film with the conductive material included in the interconnection 160b. If the interconnection 160b includes a metal, the capping film 170 may include a metal nitride formed at an interface between the top surface of the interconnection 160b and the capping film 170. If the interconnection 160b includes copper, the capping film 170 may include copper nitride (CuN) foamed at an interface between the top surface of the interconnection 160b and the capping film 170.

The capping film 170 may minimize diffusion of conductive material in the interconnections 160b into other films via current and/or heat.

Referring to FIGS. 12A and 12B, a dielectric film 180 may be formed over the contact mold layer 120. The dielectric film 180 can completely fill the spaces 133 between the interconnections 160b. The dielectric film 180 may be formed by a chemical vapor deposition process, a physical vapor deposition process or an atomic layer deposition process. The dielectric film 180 may be formed as a single layer or as multiple layers. The dielectric film 180 may include a low dielectric material having a dielectric constant less than that of a nitride. For example, the dielectric film 180 may include an oxide or silicon oxycarbide. Including a low dielectric material in the dielectric film 180 may minimize a parasitic capacitance between the interconnections 160b, thus improving reliability and electrical properties of a semiconductor device.

According to embodiments of the inventive concept, since the diffusion coefficient of mobile atoms in the contact mold layer 120 is greater than a diffusion coefficient of mobile atoms in a nitride, mobile atoms in the films of a semiconductor device may be emitted from the semiconductor device through the contact mold layer 120, minimizing effects that occur due to the presence of these mobile atoms. The capping film 170 may cover top surfaces of the interconnections 160b. Accordingly, the capping film 170 may minimize diffusion of conductive material in the interconnection 160b into other films via current and/or heat, thus improving reliability and electrical properties of a semiconductor device.

According to embodiments of the inventive concept, since the interconnection mold layer 130 includes a material having an etching selectivity with respect to the contact mold layer 120, etching of the contact mold layer 120 may be minimized when etching the interconnection mold layer 130 to form the contact holes 125. Thus, a process for forming a semiconductor device may be simplified and a cost for manufacturing a semiconductor device may be reduced.

In addition, the contact hole 125 may be aligned with an inner wall of the groove 149 to prevent misalignments between the groove 149 and the contact hole 125. A process margin of semiconductor device may be improved and spaces between the grooves 149 may be minimized. Therefore, a highly integrated semiconductor device may be fabricated.

Alternatively, the dielectric film 180 may fill a part of the space 133. FIG. 13 is a cross sectional view taken along the lines I-I′ and II-II′ of FIG. 12A to illustrate a modified dielectric film in a semiconductor device in accordance with other embodiments of the inventive concept.

Referring to FIG. 13, a dielectric film 180 may be formed over the contact mold layer 120 so that gaps 185 are formed in the spaces 133 between the interconnections 160b. The dielectric film 180 may have an inferior step difference coating property. As a result, an overhang may occur in an upper portion of the space 133 that may form the gap 185. According to an embodiment, an upper portion of the gap 185 may be lower than a top surface of the capping film 170.

The gap 185 may extend in the first direction parallel to the interconnections 160b. As illustrated in FIG. 13, the gap 185 may be defined by the dielectric film 180. However, the inventive concept is not limited thereto. Alternatively, the dielectric film 180 may cover an upper portion of the space 133 without extending inside the space 133 to form the gap 185 in the space 133. In this case, the gap 185 may be defined by the capping film 170 covering the sidewalls of the space 133 and the dielectric film 180.

According to a present embodiment, the gaps 185 may be formed in the spaces 133 between the interconnections 160b. Thus, a parasitic capacitance between the interconnections 160b may be minimized, thereby improving reliability and electrical properties of a semiconductor device.

Hereinafter, a semiconductor device manufactured by methods in accordance with embodiments of the inventive concept as shown in FIGS. 1A to 12A, 1B to 12B, and 13, is described with reference to FIGS. 12A, 12B, and 13. FIG. 12A is a top plan view that illustrates a semiconductor device in accordance with embodiments of the inventive concept. FIG. 12B is a cross sectional view taken along the lines I-I′ and II-II′ of FIG. 12A to illustrate a semiconductor device in accordance with embodiments of the inventive concept.

Referring to FIGS. 12A and 12B, an interlayer dielectric film 110 may be disposed on a substrate 100 and a contact mold layer 120 may be disposed on the interlayer dielectric film 110. The substrate 100 may be a silicon substrate, a germanium substrate or a silicon-germanium substrate. The interlayer dielectric film 110 may be single-layered or multi-layered. The interlayer dielectric film 110 may include an oxide, a nitride and/or an oxynitride.

The contact mold layer 120 may be single-layered or multi-layered. The diffusion coefficient of mobile atoms in the contact mold layer 120 may be greater than the diffusion coefficient of mobile atoms in a nitride. According to an embodiment, the contact mold layer 120 may include an oxide. The mobile atoms may include atoms that can move freely in a film. For example, the mobile atoms may be hydrogen.

According to an embodiment of the inventive concept, since the diffusion coefficient of the mobile atoms in the contact mold layer 120 is greater than the diffusion coefficient of the mobile atoms in a nitride, mobile atoms in other films of the semiconductor device may be emitted from the device through the contact mold layer 120, minimizing effects that occur due to the presence of these mobile atoms.

Interconnections 160b extending in parallel in a first direction may be disposed on the contact mold layer 120. The interconnections 160b may be spaced apart from each other in a second direction perpendicular to the first direction.

Spaces 133 exposing a top surface of the contact mold layer 120 may be defined between the adjacent interconnections 160b. The spaces 133 may have bottom surfaces defined by a top surface of the contact mold layer 120 and sidewalls defined by sidewalls of the interconnections 160b. The spaces 133 may extend in parallel in the first direction.

Contact portions 160a may be disposed below the bottom surfaces of the interconnections 160b. Each contact portion 160a may extend downward from a bottom surface of the interconnection 160b to penetrate the contact mold layer 120. The contact portion 160a may be connected to the interconnection 160b to form a single unitary body. In other words, the contact portion 160a may lack an interface with the interconnection 160b.

A plurality of conductive pillars 115 may be disposed in the interlayer dielectric film 110. The conductive pillars 115 may penetrate the interlayer dielectric film 110 and may be laterally spaced apart from one another. The contact portions 160a may penetrate the contact mold layer 120 to connect to top surfaces of the conductive pillars 115.

The contact portions 160a may be arranged along a first column and a second column when viewed in a top plan view. The first column and the second column may be spaced apart from each other in a first direction. The first column and the second column may be parallel to a second direction perpendicular to the first direction. The first column of contact portions 160a may not overlap the second column of contact portions 160a in the first direction. According to an embodiment, as illustrated in FIG. 12A, the contact portions 160a may have a zigzag pattern in the second direction. The conductive pillars 115 may be disposed under the contact portions 160a respectively. Accordingly, the conductive pillars 115 may be divided into a first group corresponding to the first column and a second group corresponding to the second column and the conductive pillars 115 may have a zigzag pattern in the second direction.

The conductive pillars 115 may include a conductive material. For example, the conductive pillars 115 may include a doped semiconductor (e.g., doped silicon, etc.), a metal (e.g., tungsten, etc.), a conductive metal nitride (e.g., titanium nitride or tantalum nitride), a transition metal (e.g., titanium, tantalum, etc.) or a conductive-metal-semiconductor compound (e.g., metal silicide, etc.).

The interconnections 160b may have a first width in the second direction and the contact portions 160a may have a second width in the second direction. According to an embodiment, the first and second widths may be substantially equal to each other.

According to an embodiment, the contact portions 160a may include a pair of first sidewalls extending in the first direction aligned with both sidewalls of the interconnections 160b. In other words, a sidewall of the contact portion 160a may extend into a corresponding sidewall of the interconnection 160b to form a plane perpendicular to a top surface of the substrate 100.

In addition, the contact portions 160a may include a pair of second sidewalls extending in the second direction. According to an embodiment, as illustrated in FIG. 12A, the second sidewalls of the contact portions 160a may be curved. However, embodiments of the inventive concept are not limited thereto. The second sidewalls of the contact portions 160a may have a different shape.

The contact portion 160a may include the same material as the interconnection 160b. For example, the contact portion 160a and the interconnection 160b may include a metal such as tungsten, aluminum, copper, etc. Also, the interconnection 160b and the contact portion 160a may further include a barrier metal (e.g., titanium nitride or tantalum nitride) to minimize a metal diffusion. In addition, the interconnection 160b and the contact portion 160a may further include a glue layer such as titanium or tantalum.

A capping film 170 conformally covering top surfaces of the interconnections 160b and inner sides of the spaces 133 may be disposed over the substrate 100. The capping film 170 may include an insulating material. For example, the capping film 170 may include a nitride.

According to an embodiment, the capping film 170 may include a metal nitride at an interface between the top surface of the interconnection 160b and the capping film 170. If the interconnection 160b includes copper, the capping film 170 may include copper nitride (CuN) at the interface between the top surface of the interconnection 160b and the capping film 170.

The capping film 170, by covering top surfaces of the interconnections 160b, may minimize diffusion of conductive materials included in the interconnections 160b into other films via current and/or heat. Thus, a semiconductor device having improved reliability and electrical properties may be fabricated.

A dielectric film 180 filling the spaces 133 may be disposed on the contact mold layer 120. According to an embodiment, the dielectric film 180 may completely fill the spaces 133. The dielectric film 180 may be single-layered or a multi-layered. According to an embodiment, the dielectric film 180 may include a low dielectric material having a dielectric constant less than that of a nitride. For example, the dielectric film 180 may include an oxide or silicon oxycarbide. Including a low dielectric material in the dielectric film 180 may minimize a parasitic capacitance between the interconnections 160b, thus improving reliability and electrical properties of the semiconductor device.

According to embodiments of the inventive concept, since the diffusion coefficient of mobile atoms in the contact mold layer 120 is greater than the diffusion coefficient of mobile atoms in a nitride, mobile atoms in other films of the semiconductor device may be emitted from the device through the contact mold layer 120, minimizing effects that occur due to the presence of these mobile atoms. The capping film 170, by covering top surfaces of the interconnections 160b, may minimize diffusion of conductive materials in the interconnections 160b into other films via current and/or heat. Thus, a semiconductor device having improved reliability and electrical properties may be fabricated.

Alternatively, the dielectric film 180 may fill a part of the space 133. FIG. 13 is a cross sectional view taken along the lines I-I′ and II-II′ of FIG. 12A to illustrate a modified semiconductor device in accordance with other embodiments of the inventive concept.

Referring to FIGS. 12A and 13, gaps 185 surrounded by the dielectric film 180 may be disposed in the spaces 133 between adjacent interconnections 160b. The dielectric film 180 may extend along an inner side of the space 133 to cover an upper portion of the space 133. According to an embodiment, an upper portion of the gap 185 may be lower than a top surface of the capping film 170. The gap 185 may extend in the first direction parallel to the interconnections 160b.

As illustrated in FIG. 13, the gap 185 may be disposed in the dielectric film 180. However, embodiments of the inventive concept are not limited thereto. Alternatively, the dielectric film 180 may cover the upper portion of the space 133 without extending inside the space 133. In this case, the gap 185 may be defined by the capping film 170 covering the sidewalls of the space 133 and the dielectric film 180.

According to a present embodiment, gaps 185 may be disposed in the spaces 133 between the interconnections 160b, thus minimizing a parasitic capacitance between the interconnections 160b and improving reliability and electrical properties of the semiconductor device.

Hereinafter, a method of forming a semiconductor device in accordance with other embodiments of the inventive concept is described with reference to the drawings. In a present embodiment, the same reference numbers refer to the same constituent elements as the aforementioned embodiments. Also, for brevity of description, the description of common features will be omitted.

A present embodiment may include the features of the aforementioned embodiments described with reference to FIGS. 1A through 10A and 1B through 10B.

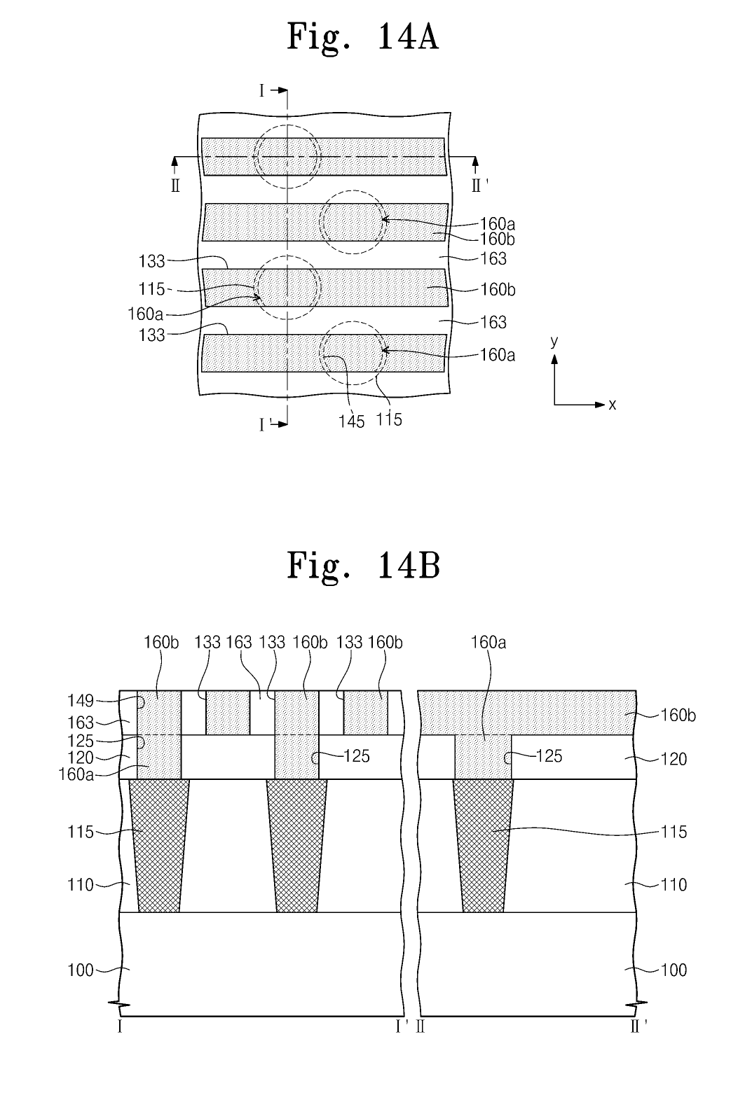

FIG. 14A is a top plan view that illustrates a method of forming a semiconductor device in accordance with other embodiments of the inventive concept. FIG. 14B is a cross sectional view taken along the lines I-I′ and II-II′ of FIG. 14A to illustrate a method of forming a semiconductor device in accordance with other embodiments of the inventive concept.

Referring to FIGS. 14A and 14B, a dielectric film filling the insides of the spaces 133 between adjacent interconnections 160b may be deposited on the substrate 100. The dielectric film may be deposited by a chemical vapor deposition process, a physical vapor deposition process or an atomic layer deposition process.

The dielectric film may be planarized to expose top surfaces of the interconnections 160b. The dielectric film may be planarized using a dry etching process or a chemical mechanical polishing process. A top surface of the planarized dielectric film 163 may be even with top surfaces of the interconnections 160b.

According to an embodiment, the planarized dielectric film 163 may completely fill the spaces 133. The planarized dielectric film 163 may include a material having a dielectric constant less than that of a nitride. For example, the planarized dielectric film 163 may include an oxide. Including a material having a dielectric constant less than that of a nitride in the planarized dielectric film 163 may minimize a parasitic capacitance between the interconnections 160b, thus improving reliability and electrical properties of the semiconductor device.

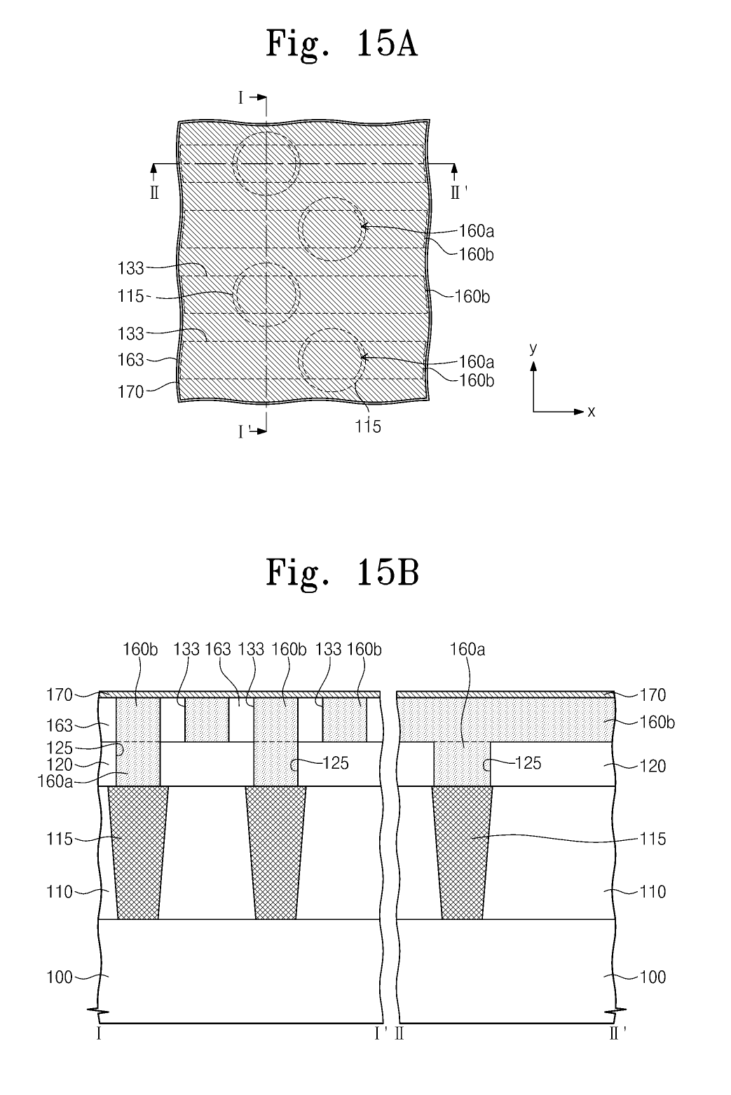

Referring to FIGS. 15A and 15B, a capping film 170 may be formed on the planarized dielectric film 163 and the interconnections 160b. According to an embodiment, the capping film 170 may be in direct contact with top surfaces of the interconnections 160b and the planarized dielectric film 163. The capping film 170 may include a dielectric film deposited by a plasma chemical vapor deposition process. The capping film 170 may include an insulating material. For example, the capping film 170 may include a nitride.

According to an embodiment, forming the capping film 170 may include depositing a dielectric film using plasma chemical vapor deposition and reacting the dielectric film with a conductive material included in the interconnection 160b. If the interconnection 160b includes a metal, the capping film 170 may include a metal nitride formed at the interface between a top surface of the interconnection 160b and the capping film 170. If the interconnection 160b includes copper, the capping film 170 may include copper nitride (CuN) formed at the interface between a top surface of the interconnection 160b and the capping film 170.

The capping film 170 may minimize diffusion of conductive materials in the interconnection 160b into other films via current and/or heat.

A semiconductor device in accordance with embodiments of the inventive concept may include a contact mold layer 120 having a diffusion coefficient of mobile atoms greater than a diffusion coefficient of mobile atoms in a nitride. Also, a semiconductor device in accordance with embodiments of the inventive concept may include an interconnection mold layer 130 including a material having an etching selectivity with respect to the contact mold layer 120. The contact hole 125 may be aligned with an inner sidewall of the groove 149 to prevent the groove 149 from being misaligned with the contact hole 125.

In addition, according to a present embodiment, the capping film 170 may cover top surfaces of the interconnections 160b. Accordingly, the capping film 170 may minimize diffusion of conductive material in the interconnection 160b into other films via current and/or heat. Thus, a semiconductor device having improved reliability and electrical properties may be fabricated.

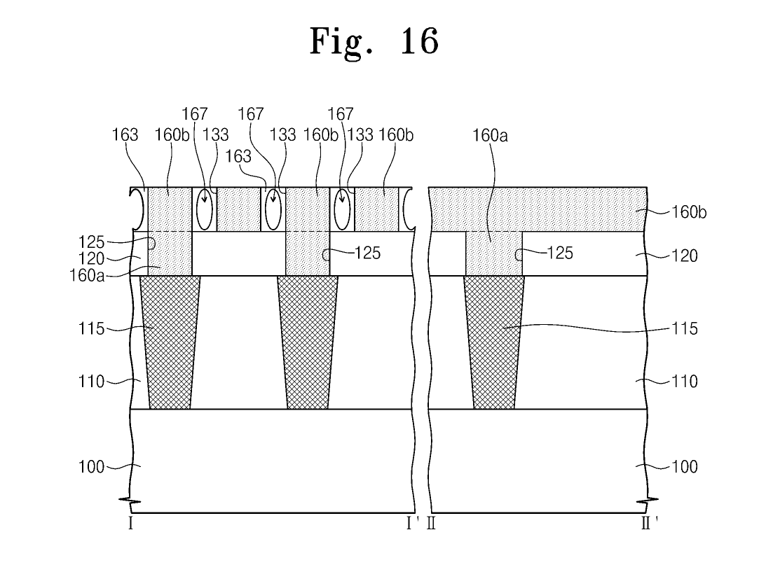

Alternatively, the dielectric film 163 may fill a part of the space 133. FIG. 16 is a cross sectional view taken along the lines I-I′ and II-II′ of FIG. 14A to illustrate a modified dielectric film in a method of forming a semiconductor device in accordance with embodiments of the inventive concept.

Referring to FIGS. 14A and 16, a dielectric film may be formed so that gaps 167 are formed in the spaces 133 between the adjacent interconnections 160b on the substrate 100. In this case, the dielectric film may have an inferior step difference coating property. As a result, an overhang may occur in an upper portion of the space 133 to form the gap 167. The dielectric film may be deposited by a chemical vapor deposition process or a physical vapor deposition process.

The dielectric film may be planarized to expose top surfaces of the interconnections 160b. The dielectric film may be planarized using at least one of a dry etching process or a chemical mechanical polishing process.

According to an embodiment, an upper portion of the gap 167 may be lower than top surfaces of the interconnections 160b. Thus, an upper portion of the gap 167 may be closed by the planarized dielectric film 163. The gap 167 may extend in the first direction parallel to the interconnections 160b.

As illustrated in FIG. 16, the gap 167 may be defined by the planarized dielectric film 163. However, embodiments of the inventive concept are not limited thereto. Alternatively, the planarized dielectric film 163 may cover an upper portion of the space 133 without extending into the space 133 to form the gap 167. In this case, the gap 167 may be defined by the sidewalls of the space 133 and the planarized dielectric film 163.

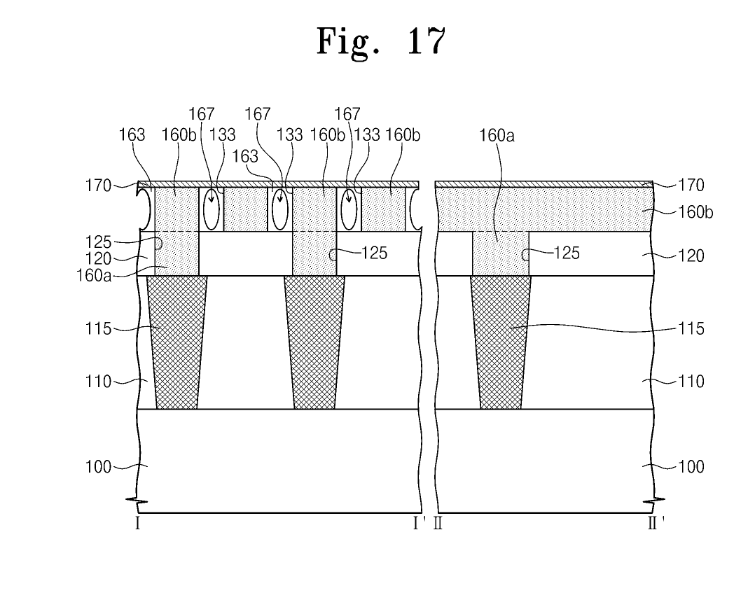

Referring to FIGS. 15A and 17, a capping film 170 may be formed on the planarized dielectric film 163 and the interconnections 160b. According to an embodiment, the capping film 170 may be in direct contact with top surfaces of the interconnections 160b and the planarized dielectric film 163. The capping film 170 may include a dielectric film deposited by a plasma chemical vapor deposition process. The capping film 170 may include an insulating material. For example, the capping film 170 may include a nitride.

According to an embodiment, forming the capping film 170 may include depositing a dielectric film using a plasma chemical vapor deposition process and reacting the dielectric film with a conductive material included in the interconnection 160b. If the interconnection 160b includes a metal, the capping film 170 may include a metal nitride formed at an interface between a top surface of the interconnection 160b and the capping film 170. If the interconnection 160b includes copper, the capping film 170 may include copper nitride (CuN) formed at an interface between a top surface of the interconnection 160b and the capping film 170.

In addition, according to a present embodiment, the capping film 170 may cover top surfaces of the interconnections 160b. Accordingly, the capping film 170 may minimize diffusion of conductive materials in the interconnection 160b into other films via current and/or heat. Gaps 167 formed in the spaces 133 between the interconnections 160b may minimize a parasitic capacitance between the interconnections 160b. Thus, reliability electrical properties of a semiconductor device may be improved.

Hereinafter, a semiconductor device manufactured by methods in accordance with embodiments of the inventive concept as shown in FIGS. 14A to 15A, 14B to 15B, and 16-17, is described with reference to FIGS. 15A-B and 17. FIG. 15A is a top plan view that illustrates a semiconductor device in accordance with other embodiments of the inventive concept. FIG. 15B is a cross sectional view taken along the lines I-I′ and II-II′ of FIG. 15A.

In the present embodiment, the same reference numbers refer to same constituent elements as the aforementioned embodiments. Also, for brevity of description, the description of common features will be omitted.

Referring to FIGS. 15A and 15B, a dielectric film 163 may be disposed in spaces 133 between adjacent interconnections 160b. According to an embodiment, the dielectric film 163 may completely fill the spaces 133. A top surface of the dielectric film 163 may be substantially even with top surfaces of the interconnections 160b.

The dielectric film 163 may include a material having a dielectric constant less than that of a nitride. For example, the dielectric film 163 may include an oxide. Including a material having a dielectric constant less than that of a nitride in the dielectric film 163 may minimize a parasitic capacitance between the interconnections 160b, thus improving reliability and electrical properties of a semiconductor device.

A capping film 170 may be disposed on the dielectric film 163 and the interconnections 160b. The capping film 170 may be in direct contact with top surfaces of the interconnections 160b and the dielectric film 163. The capping film 170 may include an insulating material. For example, the capping film 170 may include a nitride. According to an embodiment, the capping film 170 may include a metal nitride at an interface between a top surface of the interconnection 160b and the capping film 170. If the interconnection 160b includes copper, the capping film 170 may include copper nitride (CuN) at an interface between a top surface of the interconnection 160b and the capping film 170.

Similar to embodiments described above, a semiconductor device in accordance with a present embodiment may include a contact mold layer 120 whose diffusion coefficient for mobile atoms is greater than the diffusion coefficient or mobile atoms in a nitride.

In addition, according to a present embodiment, the capping film 170 covers top surfaces of the interconnections 160b and may minimize diffusion of conductive materials in the interconnections 160b into other films via current and/or heat. Thus, a semiconductor device having improved reliability and electrical properties may be fabricated.

Alternatively, the dielectric film 163 may fill a part of the spaces 133. FIG. 17 is a cross sectional view taken along the lines I-I′ and II-II′ of FIG. 15A to illustrate a modified dielectric film 163 according to other embodiments.

Referring to FIGS. 15A and 17, gaps 167 surrounded by a dielectric film 163 may be disposed in spaces 133 between adjacent interconnections 160b on the contact mold layer 120. The dielectric film 163 may extend along the sidewalls of the space 133 and cover a portion of the space 133. A top surface of the dielectric film 163 may be substantially even with top surfaces of the interconnections 160b.

An upper portion of the gap 167 may be lower than top surfaces of the interconnections 160b. Thus, the gap 167 may be enclosed by the dielectric film 163. The gap 167 may extend in the first direction parallel to the interconnections 160b.

As illustrated in FIG. 17, the gap 167 may be disposed in the dielectric film 163. However, embodiments of the inventive concept are not limited thereto. Alternatively, the dielectric film 163 may cover an upper portion of the space 133 without extending into the space. In this case, the gap 167 may be defined by the capping film 170 covering the space 133 and the dielectric film 163.

A capping film 170 may be formed on the dielectric film 163 and the interconnections 160b. The capping film 170 may be in direct contact with top surfaces of the interconnections 160b and the dielectric film 163. The capping film 170 may include an insulating material. For example, the capping film 170 may include a nitride. According to an embodiment, the capping film 170 may include a metal nitride at an interface between a top surface of the interconnection 160b and the capping film 170. If the interconnection 160b includes copper, the capping film 170 may include copper nitride (CuN) at an interface between a top surface of the interconnection 160b and the capping film 170.

According to a present embodiment, the capping film 170 may cover top surfaces of the interconnections 160b. Accordingly, the capping film 170 may minimize diffusion of conductive materials in the interconnection 160b into other films via current and/or heat. Gaps 167 may be formed in spaces 133 between the interconnections 160b to minimize a parasitic capacitance between the interconnections 160b. Thus, a semiconductor device having an improved reliability and electrical properties may be fabricated.

Semiconductor devices disclosed in exemplary embodiments described above may be mounted with various types of packages. For example, the semiconductor devices may be mounted on various types of packages, such as a PoP (package on package), a ball grid array (BGA), a chip scale package (CSP), a plastic leaded chip carrier (PLCC), a plastic dual in-line package (PDIP), a die in waffle pack, a die in wafer form, a chip on board (COB), a ceramic dual in-line package (CERDIP), a plastic metric quad flat pack (MQFP), a thin quad flat pack (TQFP), a small outline (SOIC), a shrink small outline package (SSOP), a thin small outline (TSOP), a thin quad flatpack (TQFP), a system in package (SIP), a multi chip package (MCP), a wafer-level fabricated package (WFP), and a wafer-level processed stack package (WSP).

A package including a semiconductor device in accordance with embodiments of the inventive concept may further include a semiconductor device (e.g., a controller and/or a logic device) performing a different function.

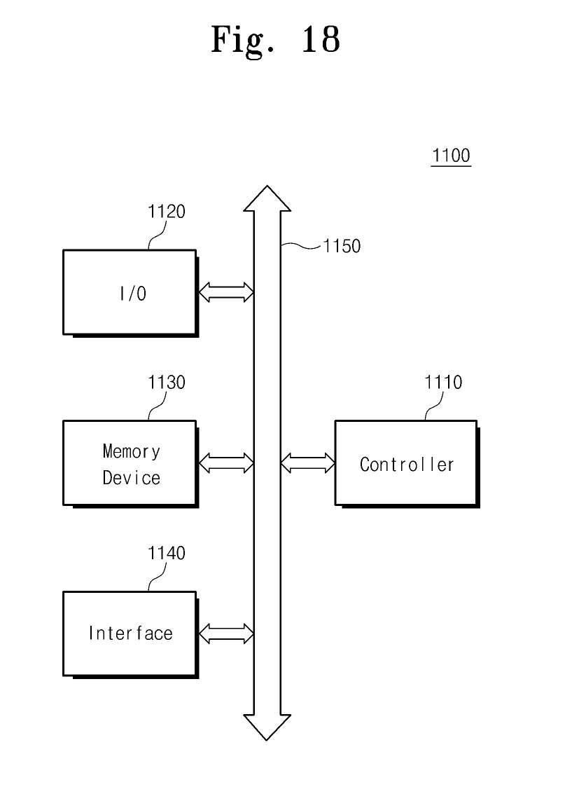

FIG. 18 is a block diagram illustrating an example of an electronic system including a semiconductor device in accordance with embodiments of the inventive concept.

Referring to FIG. 18, an electronic system 1100 in accordance with embodiments of the inventive concept may include a controller 1110, an input/output device 1120, a memory device 1130, an interface 1140 and a bus 1150. The controller 1110, the input/output device 1120, the memory device 1130 and/or the interface 1140 may be interconnected with one another through the bus 1150. The bust 1150 may correspond to a path through which data may move.

The controller 1110 may include a microprocessor, a digital signal processor, a micro controller and other logic devices that can perform functions similar thereto. If the semiconductor devices disclosed in exemplary embodiments are fabricated into a logic device, the controller 1110 may include a semiconductor device of exemplary embodiments. The input/output device 1120 may include a keypad, a keyboard and a display device. The memory device 1130 may store data and/or commands. The memory device 1130 may also include a semiconductor device in accordance with exemplary embodiments. Also, the memory device 1130 may further include different types of semiconductor devices (e.g., a DRAM device and/or a SRAM device). The interface 1140 may transmit data to a communication network or receive data from a communication network. The interface 1140 may be a wired type or a wireless type. For example, the interface 1140 may include an antenna or a wired/wireless transceiver. Although not illustrated in the drawing, the electronic system 1100 may further include a high speed DRAM device and/or a high speed SRAM device as a cache memory device to improve an operation of the controller 1110.

The electronic system 1100 may be used with a personal digital assistant (PDA), a portable computer, a web tablet, a wireless phone, a mobile phone, a digital music player, a memory card or any other electronic device that can transmit and/or receive data in a wireless environment.

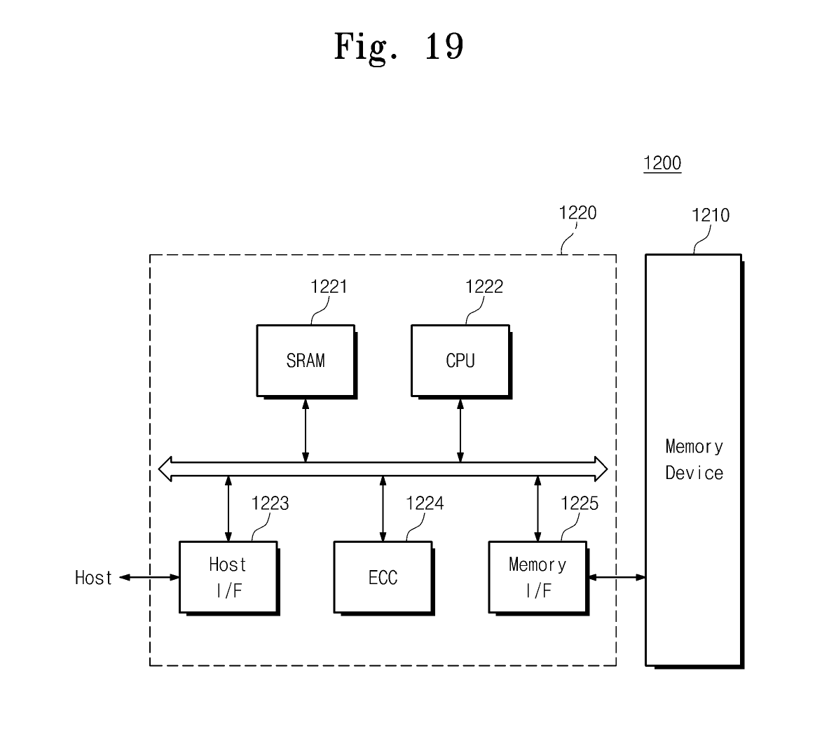

FIG. 19 is a block diagram illustrating an example of a memory card including a semiconductor device in accordance with embodiments of the inventive concept.

Referring to FIG. 19, the memory card 1200 in accordance with an embodiment of the inventive concept may include a memory device 1210. The memory device 1210 may include at least one of the exemplary embodiments described above. Also, the memory device 1210 may further include a different type of semiconductor device (e.g., a DRAM device and/or a SRAM device). The memory card 1200 may include a memory controller 1220 controlling a data exchange between a host and the memory device 1210.

The memory controller 1220 may include a central processing unit 1222 controlling the whole operation of the memory card 1200. Also, the memory controller 1220 may include an SRAM 1221 used as an cache memory of the central processing unit 1222. In addition, the memory controller 1220 may further include a host interface 1223 and a memory interface 1225. The host interface 1223 may include a data exchange protocol between the memory card 1200 and the host. The memory interface 1225 may connect the memory controller 1220 and the memory device 1210. The memory controller 1220 may further include an error correction code 1224. The error correction code 1224 may detect and correct data read out from the memory device 1210. Although not illustrated in the drawing, the memory card 1200 may further include a ROM device storing code to interface with the host. The memory card 1200 may be used as a portable data storage card. The memory card 1200 may also be a solid state device that can replace a computer hard disk.

According to a semiconductor device described above, the diffusion coefficient of mobile atoms in a contact mold layer may be greater than the diffusion coefficient of mobile atoms in a nitride. Accordingly, mobile atoms passing through films during fabrication processes that form the semiconductor device may be emitted from the device through the contact mold layer, minimizing effects that occur due to the presence of these mobile atoms. Thus, a semiconductor device having improved reliability and electrical properties may be fabricated.

Although a few embodiments of a present general inventive concept have been shown and described, it will be appreciated by those skilled in the art that changes may be made in these embodiments without departing from the principles and spirit of the exemplary embodiments of the general inventive concept, the scope of which is defined in the appended claims and their equivalents. Therefore, the above-disclosed subject matter is to be considered illustrative, and not restrictive.

1-9. (canceled)

10. A semiconductor device comprising:
a contact mold layer disposed on a substrate;
interconnections disposed on the contact mold layer and extending in parallel in a first direction and having a width in a second direction perpendicular to the first direction;
a capping film on a top surface of the interconnections: and
contact portions extending downward from a bottom surface of the interconnection to penetrate the contact mold layer,
wherein a width in the second direction of the interconnections is the substantially same as a width in a second direction of the contact portions.

11. The semiconductor device of claim 10, further comprising a dielectric film filling at least a part of a space between the adjacent interconnections on the contact mold layer, wherein the dielectric film comprises a material having a dielectric constant less than that of a nitride.

12. The semiconductor device of claim 11, wherein the dielectric film closes an upper portion of the space between the adjacent interconnections and defines a gap in the space.

13. The semiconductor device of claim 11, wherein the capping film extends from a top surface of the interconnections to conformally cover inner sidewalls of the spaces and wherein the dielectric film is disposed on the capping film.

14. The semiconductor device of claim 11, wherein a top surface of the dielectric film is substantially even with a top surface of the interconnections and wherein the capping film covers a top surface of the interconnections and a top surface of the dielectric film.

15. A semiconductor device comprising:
a contact mold layer disposed on a substrate, wherein a diffusion coefficient of mobile atoms in the contact mold layer is greater than a diffusion coefficient of mobile atoms in a nitride;
interconnections disposed on the contact mold layer and extending in parallel in a first direction and having a width in a second direction perpendicular to the first direction;
contact portions extending downward from a bottom surface of the interconnection to penetrate the contact mold layer; and
a dielectric film filling at least a part of a space between the adjacent interconnections on the contact mold layer, wherein the dielectric film comprises a material having a dielectric constant less than that of a nitride.

16. The semiconductor device of claim 16, further comprising:
an interlayer dielectric film disposed on a substrate below the contact mold layer;
a plurality of conductive pillars disposed in and penetrating the interlayer dielectric film, wherein the contact portions connect to the conductive pillars, and the contact portions and conductive pillars are arranged along a first column and a second column spaced apart from each other in the first direction and parallel to the second direction, wherein the first column of contact portions and conductive pillar does not overlap the second column of contact portions and conductive pillar in the first direction to form a zigzag pattern in the second direction

17. The semiconductor device of claim 15, wherein the dielectric film closes an upper portion of the space between the adjacent interconnections and defines a gap in the space.

18. The semiconductor device of claim 16, further comprising a capping film disposed on a top surface of the interconnections.

19. The semiconductor device of claim 18, wherein the capping film extends from a top surface of the interconnections to conformally cover inner sidewalls of the spaces and wherein the dielectric film is disposed on the capping film.

20. The semiconductor device of claim 18, wherein a top surface of the dielectric film is substantially even with a top surface of the interconnections and wherein the capping film covers a top surface of the interconnections and a top surface of the dielectric film.
